(19) United States
(12) Patent Application Publication
(10) Pub. No.: US 2010/0219836 A1
(43) Pub. Date: Sep. 2, 2010

(54) METHOD AND ARRANGEMENT FOR DETERMINING ENERGY SOURCE UNIT STATUS

(75) Inventors: Jan-Olof SVENSSON, Kivik (SE); Mats WOLF, Sodra Sandby (SE); Kent HANSSON, Bara (SE)

Correspondence Address: HARRITY & HARRITY, LLP, 11350 RANDOM HILLS ROAD, SUITE 600, FAIRFAX, VA, 22030, US

(73) Assignee: Sony Ericsson Mobile Communications AB, Lund (SE)

(21) Appl. No.: 12/396,357

(22) Filed: Mar. 2, 2009

(51) Int. Cl. G01R 31/36

(52) U.S. Cl. 324/426

(57) ABSTRACT

A method performed by an electronic device may determine a status of an energy source unit indicating performance of the energy source unit residing in the electronic device. The method may include performing a measurement over the energy source unit to produce a measured value that may be compared with a predetermined value, to generate a difference value, and the status of the energy source unit may determined based on the difference value.

### TECHNICAL FIELD

The invention generally relates to a system for determining a status of an energy source unit associated with an electronic device and, more particularly, to measuring a usable power level of an energy source.

### BACKGROUND

Today, features in communication terminals, such as cellular phones or the like, are increasing in numbers, adding value to services accessed by a user of the communication terminal. The user is, for example, informed graphically about the remaining capacity of a rechargeable battery of the communication terminal in the graphic user interface of the communication terminal. The remaining capacity may be illustrated as a battery filled to a level indicative of the remaining capacity of the battery and/or as a percentage of the fully charged battery. However, the fully charged capacity of the battery as well as the time to drain a fully charged battery changes over the life of the battery as a function of time due to reduced performance/status of the battery and the like. Ultimately, the battery may need to be replaced due to the low performance of the battery and the user or a service center replaces the battery with a new battery. In some designs of mobile terminals, batteries may be embedded in the mobile terminal such that only a service center should exchange batteries. An existing problem occurs when a customer returns or complains about an electronic device having a battery with a shortened charge state, and the battery is replaced without actually demonstrating poor performance, thereby leading to an occasional waste of resources and time.

### SUMMARY

Embodiments described herein provide improved techniques of error detection of an electronic device.

In some embodiments, a method in an electronic device for determining a status of an energy source unit indicating performance of the energy source unit mounted within the electronic device is provided. The method includes performing a measurement over the energy source unit that results in a measured value. The measured value is compared with a predetermined value resulting in a difference value, and the status of the energy source unit is determined based on the difference value.

In some embodiments, the method further includes storing the status of the energy source unit.

In addition, the status indicating whether to replace the energy source unit or not may be displayed.

Furthermore, the method may include to run at least one application in which the measurement is performed during the at least one application.

In addition, the predetermined value may, in some embodiments, be a value of a measurement from running the at least one application when the energy source unit is new/just manufactured/just put into the terminal; determined from a nominal specification of a battery type; and/or the like.

The at least one application may, in some embodiments, already be included in the electronic device with a known current consumption and the at least one application may be initiated manually from a menu displayed in the electronic device.

The measured value may include a measured time, voltage and/or the like.

In some embodiments, an arrangement for an electronic device is provided, in which the arrangement is adapted to determine a status of an energy source unit indicating performance of the energy source unit mounted within the electronic device. The arrangement may include a control unit arranged to perform a measurement over the energy source unit resulting in a measured value and to compare the measured value with a predetermined value resulting in a difference value. The control unit is further arranged to determine the status of the energy source unit based on the difference value.

The control unit may, in some embodiments, further be arranged to store the status in a memory of the arrangement.

In some embodiments, the control unit is further arranged to display the status indicating whether to replace the energy source unit or that the energy source performance is fine in the electronic device.

Furthermore, control unit may be arranged to run at least one application in which the control unit is arranged to perform the measurement during the at least one application.

In some embodiments, the predetermined value may be a value of a measurement from running the at least one application when the energy source unit is new/just manufactured/just put into the terminal; determined from a nominal specification of a battery type; and/or the like.

The at least one application may be existent in the electronic device with a known current consumption.

The measured value may in some embodiments may include a measured time, voltage, current, and/or the like.

The application may be arranged to be initiated manually from a menu displayed in the electronic device.

The arrangement may, in some embodiments, include the energy source unit.

In some embodiments, an electronic device including an arrangement adapted to determine a status of an energy source unit indicating performance of the energy source unit mounted within the electronic device is provided. The arrangement may include a control unit arranged to perform a measurement over the energy source unit resulting in a measured value; to compare the measured value with a predetermined value resulting in a difference value; and to determine the status of the energy source unit based on the difference value.

The electronic device may, in some embodiments, include the energy source unit that includes a battery embedded within the electronic device.

In some embodiments, a battery pack including an arrangement for an electronic device arranged to determine a status of an energy source unit indicating performance of the energy source unit mounted within the electronic device is provided. The arrangement may include a control unit arranged to perform a measurement over the energy source unit resulting in a measured value; to compare the measured value with a predetermined value resulting in a difference value, and to determine the status of the energy source unit based on the difference value. The arrangement may further include the energy source unit and a memory unit.

As implemented above, a simple reference for an energy source unit performance, such as a battery performance, may be used to demonstrate (to the customer, service personnel) whether battery performance is acceptable or not without having to dismount the battery from a connected state.

### BRIEF DESCRIPTION OF THE DRAWINGS

Embodiments will now be described in more detail in relation to the enclosed drawings, in which:

FIG. 1 shows a schematic overview of a mobile terminal;

FIG. 2 shows a schematic overview of a graphical menu of a mobile terminal;

FIG. 3 shows a schematic overview of a graphical menu of a mobile terminal;

FIG. 4 shows a schematic diagram of a discharge of a battery in a first state;

FIG. 5 shows a schematic diagram of a discharge of a battery in a second state;

FIG. 6 shows a schematic overview of a method in an electronic device; and

FIG. 7 shows a schematic overview of an electronic device.

### DETAILED DESCRIPTION

Various embodiments of the present invention will now be described more fully hereinafter with reference to the accompanying drawings. However, this invention should not be construed as limited to the embodiments set forth herein. Rather, these embodiments are provided so that this disclosure will be thorough and complete, and will convey the scope of the invention to those skilled in the art.

It will be understood that, as used herein, the term “comprising” or “comprises” is open-ended, and includes one or more stated elements, steps and/or functions without precluding one or more unstated elements, steps and/or functions. As used herein, the singular forms “a”, “an” and “the” are intended to include the plural forms as well, unless the context clearly indicates otherwise. The term “and/or” and “/” includes any and all combinations of one or more of the associated listed items. In the drawings, the size and relative sizes of regions may be exaggerated for clarity. Like numbers refer to like elements throughout.

Some embodiments may be embodied in hardware and/or in software (including firmware, resident software, micro-code, etc.). Accordingly, as used herein, the term “signal” may take the form of a continuous waveform and/or discrete value(s), such as digital value(s) in a memory or register. Furthermore, various embodiments may take the form of a computer program product on a computer-usable or computer-readable storage medium having computer-usable or computer-readable program code embodied in the medium for use by or in connection with an instruction execution system. Accordingly, as used herein, the terms “control unit” may take the form of digital circuitry, such as computer-readable program code executed by an instruction processing device(s) (e.g., general purpose microprocessor and/or digital signal processor), and/or analogue circuitry.

Embodiments are described below with reference to block diagrams and operational flow charts. It is to be understood that the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved. Although some of the diagrams include arrows on communication paths to show a primary direction of communication, it is to be understood that communication may occur in the opposite direction to the depicted arrows.

As used herein, an electronic device may comprise a “mobile terminal” or terminal. A mobile terminal or terminal includes, but is not limited to, any portable electronic device. The mobile terminal may be configured to transmit/receive communication signals via a long range wireless interface such as, for example, a cellular interface, via a short range wireless interface such as, for example, a Near Field Communication (NFC) interface, a Bluetooth wireless interface, a wireless local area network (WLAN) interface such as IEEE 801.11a-g, and/or via another radio frequency (RF) interface. Example terminals include, but are not limited to, cellular phones, PDAs, and mobile computers that are configured to communicate with other terminals via a cellular communication network, a Bluetooth communication network, WLAN communication network, and/or another RF communication network. Other terminals may be media players, cameras and or the like.

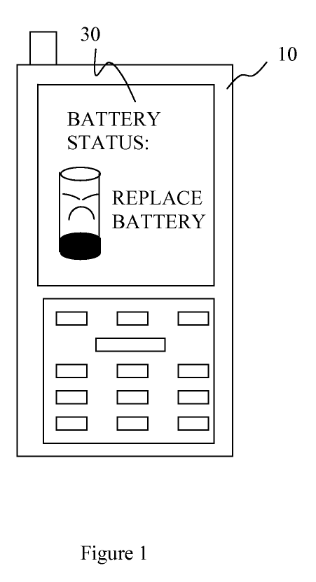

In FIG. 1, a schematic overview of an electronic device being a wireless mobile terminal 10 containing an energy source needing supervision, such as a battery, is shown.

Terminal 10 may include a function that is executed to determine status of the connected battery being the energy source of the terminal. The function may be initiated periodically, manually, automatically and/or the like, for example, during times when the usage of the terminal is low such as during night time and/or the like. The function may be executed by an application wherein test values (time, voltage) from a new/nominal battery are compared to values of the present battery.

Accordingly, a simple reference for battery performance may be used to demonstrate (to the customer, service staff) whether battery performance is acceptable or not. In the illustrated embodiment, the function generates an illustration of a “sad-faced” battery, qualitatively indicating that the battery needs to be replaced in a graphical user interface 30 of the terminal. Hence, a battery, such as an embedded battery, need not be removed to be tested to determine a performance level of the battery.

By the use of carefully selected, well-known, current consumption applications (already included in the phone/device), or measurement of actual battery performance using existing applications, the state-of-health of the battery to the customer may be determined. This may lead to customer service personnel getting an easy reference level for customers, as well as a basis to explain to/persuade the customer not to concern themselves regarding battery performance when it comes to embedded/replaceable batteries. As an example, a manufacturer may issue a credit to a consumer for poor-performing batteries if shown, for example, <80% of usable life, using built in monitoring, within 2 years of initial sale. Of course this would also include the possibility to monitor different usage factors, (number of charge cycles, total use-time, use-environment, etc.).

Different implementations of the battery performance detection/indication include:

End user: User is uncertain if battery is operating adequately or has associated diminished performance. The user enters the status menu and can directly read the status of the battery life. The status may be shown, for example, in the phone information menu and qualitatively and/or quantitatively indicate if battery is performing within an expected lifespan range.

Service center: Service Technician receives a phone for which the user complains of poor/substandard battery performance. The service technician may open the service menu and directly read the status and amount of charge cycles performed since last being reset. It can then be determined whether the battery performance is considered as one of under-performing or being in-range with normal battery life expectancy, taking into account particular usage conditions.

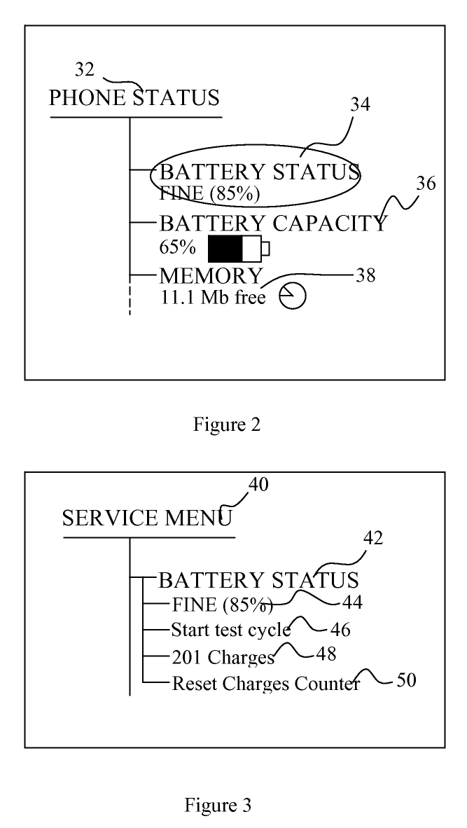

In FIG. 2, a schematic overview of a graphical menu of a mobile terminal is shown.

The graphical menu of the mobile terminal may include different features and/or functions. A user may, for example, start an application in a menu but may concurrently retrieve information about the operating performance of the mobile phone. In the illustrated example, a menu view shows a phone status 32 including a battery status 34, a battery capacity 36, and a memory 38 indicating free memory space/capacity.

Battery status 34 may indicate a current performance level of the battery installed in the mobile terminal. The performance level may be based on a result of a comparison of a performance of a first (reference) state of the battery and a performance of a second (present) state of the battery. The performance level corresponding to the first state may indicate performance of the battery just after manufacturing, at a time of installment, at a time of initial use, a nominal performance of a battery of a particular type, series, etc., an original state, and/or the like. The performance level corresponding to the second state may indicate the performance at the moment, at the most recent execution of a “determine performance”—application, and/or the like.

In FIG. 3, an exemplary embodiment of a graphical menu of a mobile terminal is shown.

In the illustrated example, a service menu is shown. The service menu may include one or menus/sub-menus that may be retrieved by pressing keys in a preset sequence of a keypad and/or other input mechanism of the mobile terminal. In some embodiments, the service menu may be intended to be accessed by authorized service staff during service of the mobile terminal corresponding to a certain sequence of keys be activated to display the service menu, for example, in accordance with manufacturer specifications.

From the service menu, a battery status 42 may be obtained; battery status 42 may include a first indication 44 of the performance stating whether the battery power is at or below an acceptable; a first selectable menu item 46 may enable a user to manually initiate a self-test cycle, a second indication 48 may indicate a number of times the battery has been at least partially and/or substantially fully recharged, a second selectable menu item 50 may enable a user to reset a counter counting the number of times a battery has been charged, for example, to be executed after battery replacement; and/or one or more other selectable items, functions, performance indications, and/or the like.

The following items are illustrated in the example under menu item “Battery Status” 42 in Service Menu 40:

Battery status (same as in Phone info menu) 44,

Initiate a test of the battery status 46,

Number of Full cycle charges since reset 48, and

Reset of Full Charge cycle counter 50.

It should be understood that other items may also be considered and displayed, for example, temperature limits exceeded, measurements of humidity of the mobile terminal being in an operational state, registering that the mobile terminal has been subjected to high impact and/or the like. Different arrangements may be used to register these events.

There are different implementations where the battery status may be used. For example:

A Service Technician receives a mobile terminal for which the user complains about poor battery performance of, for example, a mobile terminal with an embedded battery. The service technician may access the service menu and initiate a testing sequence in which the actual battery capacity is measured by performing a charge/discharge cycle, a result of which may be compared with a nominal specification for the particular battery type; and/or

A user whom is uncertain as to battery performance may enter the status menu to qualitatively and/or quantitatively ascertain the battery performance status. The status may be shown in the phone information menu and qualitatively and/or quantitatively indicate whether the battery is performing within expected lifespan, and/or the like.

It may be possible to read the life time status of the battery package from the Phone Information menu and/or from a selection in the Service menu. It may also be a service that is displayed after an application has been executed to determine the life time status of the battery package.

It should be noted that an embedded battery may cause the user to send the device to a repair center every time the user suspects the battery is out of capacity, that is, has a poor performance or the like. If no diagnostics exist, it will typically result in a battery replacement. The feature of displaying the battery status of the embedded battery (as well as a battery exchangeable by the user) will remove a fair amount of uncertainty and will reduce the amount of “no trouble found” runs in repair.

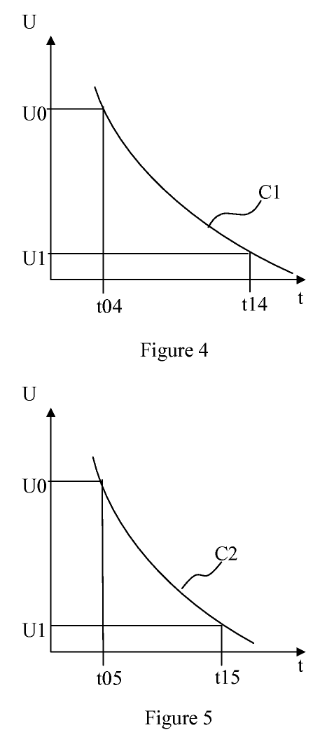

In FIG. 4, a schematic diagram of a voltage curve C1 indicating a discharge of a battery is shown.

In the illustrated example, the curve C1 is illustrating a nominal curve of the battery, the battery being in a new state, just manufactured, from a specification of the battery, and/or the like. A first voltage U0 is preset to a certain voltage corresponding to a first time T04; from the curve one may then read a second voltage U1 at a second T14 indicating the battery as being discharged.

In FIG. 5, a schematic diagram of a curve C2 indicating a discharge of a battery.

In the illustrated example, the curve C2 is illustrating a voltage curve of the battery, the battery being in a used state, recharged a number of times, used over a period of time and/or the like. A first voltage U0 is preset to a certain voltage corresponding to a first time T05 defined as a start voltage (for example, indicating a fully loaded battery). From the curve C2, a second voltage U1 indicating the battery as being discharged at a second T15 may be determined.

An application may then compare a second discharge time T15−T05 of FIG. 5 with a first discharge time of FIG. 4, T14−T04, where a result of the comparison may indicate the performance of the battery at the used state of FIG. 5. For example, (T15−T05)/(T14−T04)=percentage of original performance. This is a very simplified example and different ways of determining the present performance of the battery may be used. For example, it should be understood that the more a battery is used, the voltage of a battery under a given load may be reduced; this may also be measured to indicate performance of the used battery.

Another application may be to determine, for example, a Direct Current resistance of a battery based on a pre-determined pulsed load or loads, a voltage recovery time based on pre-determined load or loads, voltage rise time based on given input or charge current, to run some Global System for Mobile communications GSM load and compare to a predetermined threshold value, and/or the like.

To determine performance, an application may be initiated manually, automatically initiated in a periodic routine manner in the mobile terminal (for example, every month, after every hundredth charging, automatically when fully charged after a recharging cycle, and disconnected from the electricity network, and/or the like). The determination of performance may also be performed by initiating a number of known applications of the mobile terminal and to perform measurements based on the execution of the known applications, wherein the energy consumptions of the applications are known.

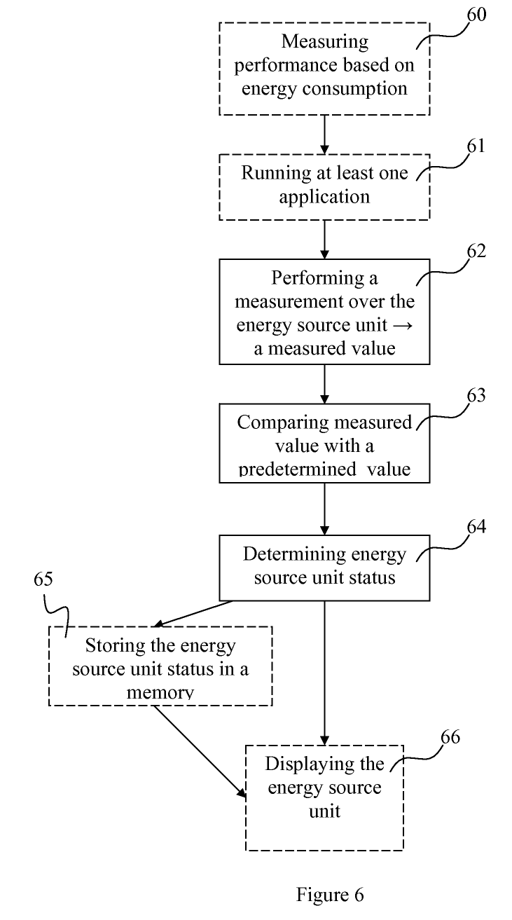

In FIG. 6, a method in an arrangement of an electronic device is shown. The electronic device may be a mobile terminal such as a mobile phone, a media player, a camera device, and/or the like; any device powered by a rechargeable battery or other limited-life power source. The method may be implemented for determining a performance level of an energy source of the electronic device against a performance level threshold. The performance of the energy source may be determined for the energy source existing in a second state. This performance may then be compared to a performance of the energy source being in a first state. The first state may be when the energy source is new/just manufactured/just placed in service in the terminal/a nominal state/initially charged, and/or the like. The second state may be when the energy source has been used, for example, a present state, a state after a certain time after manufacturing, a state after a number of charging cycles, and/or the like.

In some embodiments, the electronic device may include an embedded energy source unit (an embedded battery pack), in which the energy source unit may not be removable and/or accessible without disassembly and/or destruction of the energy source unit, and authorized service staff may have to use, for example, specialized tools to disassemble the electronic device to remove the energy source unit to perform a test on the energy source unit. By providing a method performed within the electronic device while maintaining the electronic device in an operational state (i.e., without pausing operation or the need to disassemble the electronic device), an efficient and reliable manner to determine performance of the energy source unit of the electronic device may be achieved. In some embodiments, the method of determining the performance of the energy source may be performed by an arrangement within a pack comprising the energy source: a so-called, smart battery pack. In some embodiments, the energy source unit may include a replaceable battery.

In exemplary step 60, the arrangement within the electronic device may perform at least one measurement related to the energy consumption of the energy source unit. This measurement may generate a result as a first measured value and may be performed when the energy source unit is newly manufactured/initially installed in the terminal, and/or the like.

In exemplary step 61, at least one application may be executed to determine a current performance of the energy source unit (i.e., the time that the application is executed). In some embodiments, the application is initiated manually from a menu displayed in the electronic device. The application may be initiated automatically when the energy source unit has been fully charged a preset of times. For example, a counter within the electronic device may count the number of times a battery is fully charged (fully charged for example being a preset voltage of measured voltage of the energy source unit).

In some embodiments, a triggering event to initiate the determination of performance of the energy source unit may be when a connection to the electricity network is disconnected, for example, when the charger is disconnected from the electronic device/no feeding current is detected to the energy source.

In step 62, the arrangement within the electronic device performs a measurement over the energy source unit resulting in a measured value. It should here be understood that a plurality of known applications may be executed in which the energy consumption of the different applications are known and measurements are performed over the executions of these known applications. In some embodiments, the step of performing a measurement is performed during the at least one application. In some embodiments, the measured value includes an objective parameter, such as measured time, voltage, a time-rate-of-change associated with usable battery life, for example, from a fully/partially charged state, scheduled degradation of battery life, and/or the like.

In step 63, the arrangement within the electronic device may compare the measured value with a predetermined value to determine a difference value. The predetermined value may include the first measured value, a value determined from a nominal specification of a type of energy source unit corresponding to a type of the energy source unit of the electronic device, and/or the like.

In step 64, the arrangement within the electronic device may determine the status of the energy source unit based on the determined difference value. For example, if the difference value is calculated to be below that of a preset threshold value, the status of the energy source unit may be determined to correspond to an accepted level of functionality/state of acceptability/operational performance level/a quality of good/positive, and/or the like. However, if the difference value is calculated to exceed that of a predetermined threshold value, the status of the energy source unit may be determined to correspond to dysfunctional/negative/the battery should be replaced/bad, and/or the like. It should also be understood that when the difference value is equal to that of a preset threshold value the status may be determined to be that which is described above for one of below that of the preset threshold value or exceeding that of the preset threshold value.

In exemplary step 65, the arrangement within the electronic device may store the status of the energy source unit. This may be stored to be retrieved by service staff during repair and/or a user of the electronic device during operation.

In exemplary step 66, the electronic device may display the status, whereby the displaying of the status may indicate whether to replace the energy source unit or not. In some embodiments in which the arrangement may reside in a smart battery pack, the status may be retrieved/received from the arrangement.

Embodiments are described with reference to block diagrams and/or flowchart illustrations of methods, apparatus (systems). It is to be understood that several blocks of the block diagrams and/or flowchart illustrations, and combinations of blocks in the block diagrams and/or flowchart illustrations, can be implemented by computer program instructions. These computer program instructions may be stored on a number of computer-readable storage devices provided to a processor of a general purpose computer, special purpose computer, and/or other programmable data processing apparatus to produce a machine, such that the instructions, which execute via the processor of the computer and/or other programmable data processing apparatus, create means for implementing the functions/acts specified in the block diagrams and/or flowchart block or blocks.

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the block diagrams and/or flowchart block or blocks.

The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions/acts specified in the block diagrams and/or flowchart block or blocks.

In some implementations, the functions/acts noted in the blocks may occur out of the order noted in the operational illustrations. For example, two blocks shown in succession may in fact be executed substantially concurrently or the blocks may sometimes be executed in the reverse order, depending upon the functionality/acts involved.

In order to perform the method an arrangement is provided.

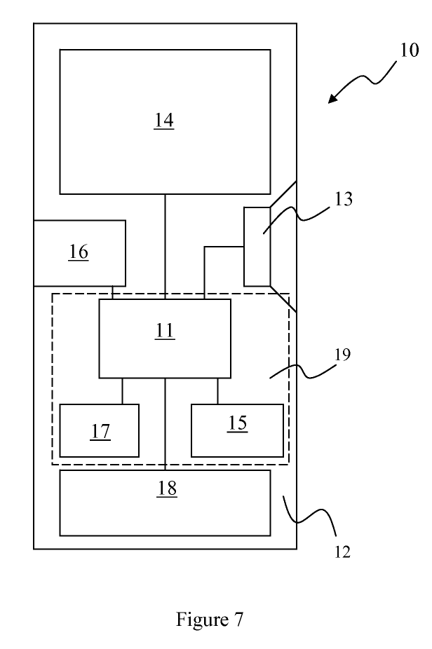

In FIG. 7, a schematic overview of an arrangement 19 in an electronic device is shown. The electronic device may include a mobile terminal, such as a mobile phone, a portable media player, a camera, and or the like. In the illustrated example, the electronic device is a mobile terminal 10.

Arrangement 19 may include a control unit 11 arranged to determine a status of an energy source unit 15, indicating performance of energy source unit 15 connected and assembled within mobile terminal 10, to supply activated units and/or elements of mobile terminal 10 with power to operate. Control unit 11 may be further arranged to perform a measurement of energy source unit 15, thereby generating a measured value, to which to compare with a predetermined value, to determine a difference value, from which a status of the energy source unit 15 may be derived.

Mobile terminal 10, in the illustrated embodiments, includes a portable housing assembly 12, a display 14, a user interface (i.e., a man machine interface (MMI)) including a speaker 13 (i.e., a sound transducer), control unit 11, a communication module 16, and a memory 17. The foregoing components of mobile terminal 10 may be included in many conventional mobile terminals.

Display 14 may be any suitable display screen assembly. For example, display screen 14 may be a liquid crystal display (LCD) with or without auxiliary lighting (e.g., a lighting panel), a touch panel and/or the like.

The user interface may include any suitable input device(s) 18 including, for example, a touch activated or touch sensitive device (e.g., a touch screen), a joystick, a keyboard/keypad, a dial, a directional key or keys, and/or a pointing device (such as a mouse, trackball, touch pad, etc.). Speaker 13 may generate sound responsive to an input audio signal. The user interface may also include a microphone coupled to an audio processor that is configured to generate an audio data stream responsive to sound incident on the microphone.

In some embodiments, control unit 11 may further support various functions of mobile terminal 10. Control unit 11 may be any commercially available and/or custom microprocessor, for example. In use, control unit 11 of mobile terminal 10 generates a display image on display 14. Control unit 11 may control the components of mobile terminal 10. However, in some embodiments where arrangement 19 is disposed in a smart battery pack, the arrangement may also include energy source unit 15; and control unit 11 is mainly directed to functions related to energy source unit 15.

Memory 17 may be configured to store digital information signals and data such as measured values and determined values relating to the power consumption and battery performance. In the embodiments of the arrangement being a smart battery pack, memory 17 may be included within the battery pack arranged to store data related to the energy source unit.

Communication module 16 may be configured to communicate data over one or more wireless interfaces to another remote wireless terminal as discussed herein. Communication module 16 may include a cellular communication module, a direct point-to-point connection module, and/or a WLAN module.

With a cellular communication module, a wireless terminal may communicate via the base station(s) of a network using one or more cellular communication protocols such as, for example, Advanced Mobile Phone Service (AMPS), ANSI-136, Global Standard for Mobile (GSM) communication, General Packet Radio Service (GPRS), enhanced data rates for GSM evolution (EDGE), code division multiple access (CDMA), wideband-CDMA, CDMA2000, Universal Mobile Telecommunications System (UMTS), Evolved Packet System (EPS comprising LTE), LTE Advanced and/or the like.

A direct point-to-point connection module may include a direct RF communication module or a direct IR communication module. The direct RF communication module may include a Bluetooth module, an NFC module and/or the like. With a Bluetooth module, the wireless terminal can communicate via an ad-hoc network through a direct point-to-point interface. With a WLAN module, the wireless terminal can communicate through a WLAN, e.g. a router, using a communication protocol that may include, but is not limited to, 802.11a, 802.11b, 802.11e, 802.11g, and/or 802.11i.

Communication module 16 may include a transceiver typically having a transmitter circuit and a receiver circuit, which respectively transmit outgoing radio frequency signals (e.g., to the network, a router or directly to another terminal) and receive incoming radio frequency signals (e.g., from the network, a router or directly to another terminal), such as voice and data signals, via an antenna. Communication module 16 may include a short range transmitter and receiver, such as a Bluetooth/NFC transmitter and receiver and/or the like. The antenna may be an embedded antenna, a retractable antenna or any antenna known to those having skill in the art without departing from the scope of the present invention. The radio frequency signals transmitted between mobile terminal 10 and the network, router or other terminal may include both traffic and control signals (e.g., paging signals/messages for incoming calls), which are used to establish and maintain communication with another party or destination. The radio frequency signals may also include packet data information, such as, for example, cellular digital packet data (CDPD) information. In addition, the transceiver may include an infrared (IR) transceiver configured to transmit/receive infrared signals to/from other electronic devices via an IR port and/or a NFC Transmitter.

Mobile terminal 10 may also be configured to electrically couple with another terminal via a wireline or cable for the transmission of digital communication signals therebetween. Mobile terminal 10 may include further components such as a camera device configured to generate a still image and/or video data stream based on incident light.

According to some embodiments, mobile terminal 10 is a handheld mobile terminal. By “handheld mobile terminal,” it is meant that the outer dimensions of the mobile terminal are adapted and suitable for use by a typical operator using one hand. According to some embodiments, the total volume of handheld mobile terminal 10 is less than about 200 cc. According to some embodiments, the total volume of the handheld terminal 10 is less than about 100 cc. According to some embodiments, the total volume of the handheld mobile terminal 10 is between about 50 and 100 cc. According to some embodiments, no dimension of handheld mobile terminal 10 exceeds about 200 mm.

In some embodiments, it should be understood that control unit 11 may be arranged to transmit a request for a new energy source unit (battery) over communication module 16 to a battery supplier in the network when the determination of the performance of energy source unit 15 indicates that energy source unit 15 needs to be replaced with new energy source unit 15. Then this may be provided as a service to the user (free, to a cost, or the like).

Control unit 11 may further be arranged to store the status, for example, in a memory of mobile terminal 10 or the memory within arrangement 19 and/or to display in display arrangement 14 the status indicating whether to replace the energy source unit or not.

In some embodiments, control unit 11 is further arranged to run at least one application, in which control unit 11 is arranged to perform the measurement during the at least one application. The application may be existent in the mobile terminal/arrangement with a known current consumption, and, in some embodiments, arranged to be initiated manually from a menu displayed in the mobile terminal, automatically when certain criteria are met (for example, a number of recharging cycles has been performed, a certain time period has passed, and/or the like). The application may further be automatically initiated when a charger connected to electricity network is plugged in/out of the mobile terminal detected by a detection circuit detecting feed current and/or the like.

In some embodiments, the predetermined value comprises a value of a measurement received from running the application when the energy source unit is new/just manufactured/just put into the terminal; determined from a nominal specification of a battery type; and/or the like. Control unit 11 may be arranged to determine type of battery by measuring voltage, resistance, current and/or the like. Control unit 11 may then based on the type of energy source unit 15 select data of a battery type corresponding to the type of energy source unit 15.

In some embodiments, the measured value comprises a measured time, voltage, current, and/or the like.

In some embodiments, energy source unit 15 may include a removable battery and in some embodiments energy source unit 15 may include a battery embedded within the mobile terminal. In some embodiments, a smart battery pack include the arrangement including the energy source unit and a memory to store battery data on.

Control unit 11 may comprise a CPU, a single processing unit, a plurality of processing units, and or the like. In some embodiments, in which the arrangement is included within a smart battery pack, control unit 11 may be included in a plurality of control units in communication with each other to perform the determination and displaying the status of the energy source. At least one control unit is arranged in the mobile terminal and at least one control unit is arranged in the arrangement.

Memory unit 17 may include a single memory unit, a plurality of memory units, external and/or internal memory units.

In the drawings and specification, there have been disclosed exemplary embodiments of the invention. However, many variations and modifications can be made to these embodiments without substantially departing from the principles of the present invention. Accordingly, although specific terms are employed, they are used in a generic and descriptive sense only and not for purposes of limitation, the scope of the invention being defined by the following claims.

What is claimed is:

1. A method, performed in an electronic device, for determining a status of an energy source unit associated with the electronic device indicating a performance level of the energy source unit, the method comprising:
performing a measurement over the energy source unit to generate a measured value;
comparing the measured value with a predetermined value to generate a difference value; and
determining, based on the difference value, the status of the energy source unit.

2. The method of claim 1, further comprising storing, in the electronic device, the status of the energy source unit.

3. The method of claim 2, further comprising displaying the status indicating one of to replace or not replace the energy source unit.

4. The method of claim 1, further comprising running at least one application associated with the electronic device, where the performing measurement is performed during the at least one application.

5. The method of claim 4, where the predetermined value is a value of a measurement obtained during the running the at least one application.

6. The method of claim 4, where the at least one application functions within the electronic device with a known current consumption.

7. The method of claim 1, where the measured value comprises at least one of a time, a voltage, or a time-rate-of-change associated with battery life shortening.

8. The method of claim 4, where the at least one application is initiated by a user by a selection from a menu displayed in the electronic device.

9. An electronic device arrangement to determine a status of an energy source unit indicating performance of the energy source unit disposed within the electronic device, comprising:
a control unit to:
obtain a measurement associated with the energy source unit to directly obtain a measured value,
compare the measured value with a predetermined value to indirectly determine a difference value, and
determine a performance state of the energy source unit based on the difference value.

10. The electronic device arrangement of claim 9, where the control unit is further to store the status in a memory of the arrangement.

11. The electronic device arrangement of claim 10, where the control unit is further to display the status indicating to one of replace or not replace the energy source unit.

12. The electronic device arrangement of claim 9, where the control unit is further arranged to run at least one application, where the control unit is to perform the measurement during the running of the at least one application.

13. The electronic device arrangement of claim 12, where the predetermined value is a value of a measurement from running the at least one application when the energy source unit is new/just manufactured/just put into the terminal; determined from a nominal specification of a battery type; and/or the like.

14. The electronic device arrangement of claim 12, where the at least one application corresponds to a known current consumption.

15. The electronic device arrangement of claim 9, where the measured value comprises at least one of a time, a voltage, a current, a rate of power dissipation, or battery usage life.

16. The electronic device arrangement of claim 12, where the at least one application is to be activated manually by a user selecting from a menu displayed in the electronic device.

17. An arrangement according to claim 9, further comprising the energy source unit.

18. An electronic device including an arrangement to determine a status of an energy source unit indicating performance of the energy source unit mounted within the electronic device comprising a control unit arranged to perform a measurement over the energy source unit resulting in a measured value, to compare the measured value with a predetermined value resulting in a difference value, and to determine the status of the energy source unit based on the difference value.

19. The electronic device of claim 18, further comprising the energy source unit that comprises a battery embedded within the electronic device.

20. A battery pack comprising an arrangement for an electronic device arranged to determine a status of an energy source unit indicating performance of the energy source unit mounted within the electronic device comprising a control unit arranged to perform a measurement over the energy source unit resulting in a measured value, to compare the measured value with a predetermined value resulting in a difference value, and to determine the status of the energy source unit based on the difference value, wherein the arrangement further comprises the energy source unit and a memory unit.
